(19) United States
(12) Patent Application Publication
(10) Pub. No.: US 2003/0193422 A1
(43) Pub. Date: Oct. 16, 2003

(54) System and method for displaying patent data in multiple encodings

(76) Inventors: Chung-I Lee, Tu-Chen (TW); Caiyang Luo, Shenzhen (CN); Xiumin Duan, Shenzhen (CN)

Correspondence Address: WEI TE CHUNG, FOXCONN INTERNATIONAL, INC., 1650 MEMOREX DRIVE, SANTA CLARA, CA, 95050, US

(21) Appl. No.: 10/279,167

(22) Filed: Oct. 23, 2002

(30) Foreign Application Priority Data
Apr. 12, 2002 (TW) 91107525

(51) Int. Cl. H03M 5/00

(52) U.S. Cl. 341/55

(57) ABSTRACT

A system for displaying patent data in multiple encodings includes a client computer (10) connected to the Internet, an application server (12), and a database server (13). The database server is used for storing patent data downloaded by the client computer. The client computer comprises application software (22) for downloading patent data via the Internet, for sending a request to access patent data in the central database server, and for displaying patent data in the form of Unicode strings on the client computer. The application server comprises a data processing interface (31) for interconversion of binary digits and Unicode strings. A related method includes: (a) sending patent data required by a user to the application server in the form of binary digits; (b) converting the binary digits into Unicode strings; and (c) sending the patent data in the form of Unicode strings to the client computer for display.

### BACKGROUND OF THE INVENTION

1. Field of the Invention

The present invention relates to systems and methods for displaying data in multiple encodings, and more specifically to a system and method for displaying patent data in multiple encodings on a client computer by interconverting binary digits and Unicode strings in an application server.

2. Background of the Invention

Language text varies tremendously across the world. Language text must be represented in digital form inside a computer and other electronic devices. Therefore, a wide variety of character sets for encoding are be used throughout the world. A different character set is used for each different language text. National patent offices around the world publish their patents in their own official languages. The texts of published patents vary from country to country. The character sets used in patent databases of the national patent offices vary from country to country. For example, the United States Patent and Trademark Office (USPTO) uses American Standard Code for Information Exchange (ASCII). In Europe, the dominant character encoding standards are the ISO 8859-X family. In China, the dominant character encoding standard is BIG2312. These various character encoding standards are divergent. The same encoding might represent different language characters in different character encoding standards. Electronic messages received from other countries are often garbled, because the receiver and sender use different character encoding standards.

The Unicode standard provides an international character encoding standard, and includes characters of all major international standards. It facilitates exchange of electronic data between computer users across the world. Computer systems can accurately store, process, transmit and display all sorts of electronic messages in different languages by using the Unicode standard. This has helped accelerate circulation of information and expansion of electronic business internationally.

Generally, in a three-tier network and database computing solution, data communication between client computers (the top tier) and database servers (the bottom tier) relies on application servers (the middle tier). FIG. 1 is a schematic diagram of a system for displaying patent data in multiple encodings in accordance with a preferred embodiment of the present invention. FIG. 1 also schematically shows a representative three-tier network and database computing solution applicable to related art. A plurality of client computers 10 (only one shown) is connected to an application server 12 via an intranet 11 for receiving data from or sending data to a central database server 13. Data are stored in the central database server 13 in the form of binary digits. Data must be converted into binary digits before being transferred to the central database server 13. The conventional process for storing of data is as follows. A client computer 10 downloads patent data from a remote patent database that is connected with the client computer 10 via the Internet. An operating system of the client computer 10 converts the downloaded patent data into Unicode strings. The Unicode strings are then sent to the application server 12, and converted into binary digits in the application server 12. Finally, the application server 12 stores the binary digits in the central database server 13 through an Open Database Connectivity (ODBC) driver of the application server 12.

The conventional process for assessing of patent data is as follows. The central database server 13 transfers relevant patent data in the form of binary digits in accordance a request from a user at the client computer 10. The binary digits are transferred to the client computer 10 after a brief stay in a system buffer of the application server 12. The operating system of the client computer 10 converts the binary digits into Unicode strings, and displays the data for the user. During the conversion from Unicode strings to binary digits by the operating system, language setting data of the operating system is added in the head of the binary digits as a parameter. The parameter plays an important role during the reverse conversion. For conversions implemented in different systems, patent data received from the application server 12 might be displayed incorrectly on the client computer 10 because of the different language settings. A solution for displaying data in multiple encodings is to install encoding conversion software in the client computer 10. U.S. Pat. No. 6,204,782 discloses a method of automatically recognizing some encodings (e.g. Unicode) by using a comparison list and converting the recognized source encodings into target encodings that the computer system can recognize and display to users. This method can display multiple encodings satisfactorily, but it also slows down operation speed and increases the cost of the system.

### SUMMARY OF THE INVENTION

Accordingly, one objective of the present invention is to provide a system for displaying patent data in multiple encodings via the Unicode standard.

Another objective of the present invention is to provide a method for correctly displaying patent data in multiple encodings on client computers without having to install encoding conversion software.

In order to achieve the objectives set forth, the present invention provides a system for displaying patent data in multiple encodings. The system comprises a client computer connected to the Internet, an application server, and a central database server. The central database server is used for storing patent data downloaded by the client computer. The client computer is used for downloading patent data via the Internet, and for accessing patent data in the central database server. The client computer comprises application software for downloading patent data via the Internet, for sending a request to access patent data in the central database server, and for displaying patent data in the form of Unicode strings on the client computer. The application server comprises a data processing interface for interconversion of binary digits and Unicode strings. A binary digit conversion program and a string conversion program of the application server are invoked to perform interconversion.

The present invention also provides a method for displaying patent data in multiple encodings, the method comprising the steps of: (a) sending patent data required by a user to the application server in the form of binary digits; (b) converting the binary digits into Unicode strings; and (c) sending the patent data in the form of Unicode strings to the client computer for display.

Other objects, advantages and novel features of the present invention will be drawn from the following detailed description of preferred embodiments of the present invention with the attached drawings, in which:

### BRIEF DESCRIPTION OF THE DRAWINGS

FIG. 1 is a schematic diagram of a system for displaying patent data in multiple encodings in accordance with a preferred embodiment of the present invention;

FIG. 2 is a structural diagram of a client computer of the system of FIG. 1;

FIG. 3 is a structural diagram of an application server of the system of FIG. 1;

FIG. 4 is a structural diagram of a central database server of the system of FIG. 1; and

FIG. 5, 6 and FIG. 7 are flowcharts of a method for displaying patent data in multiple encodings in accordance with a preferred embodiment of the present invention.

### DETAILED DESCRIPTION OF THE INVENTION

Reference will now be made to the drawing figures to describe the present invention in detail.

FIG. 1 is a schematic diagram of a system for displaying patent data in multiple encodings in accordance with a preferred embodiment of the present invention. The system comprises a client computer 10, an application server 12, a central database server 13, and an intranet 11 that connects them all together. With the development of the Internet, patent offices all over the world now have their patent databases available on the Internet. Patent information is stored in these databases, for access by users of the Internet. The client computer 10 downloads patent data via the Internet, and transfers the downloaded patent data to the central database server 13 for storage. Users can also read and analyze patent data in the central database server 13 via the client computer 10. The application server 12 provides the function of connecting the client computer 10 to the central database server 13. Patent data downloaded from the Internet is stored in the central database server 13 via the application server 12. When the client computer 10 receives patent data from the central database server 13, programs of the application server 12 are invoked. Patent data in the central database server 13 are stored in the form of binary digits.

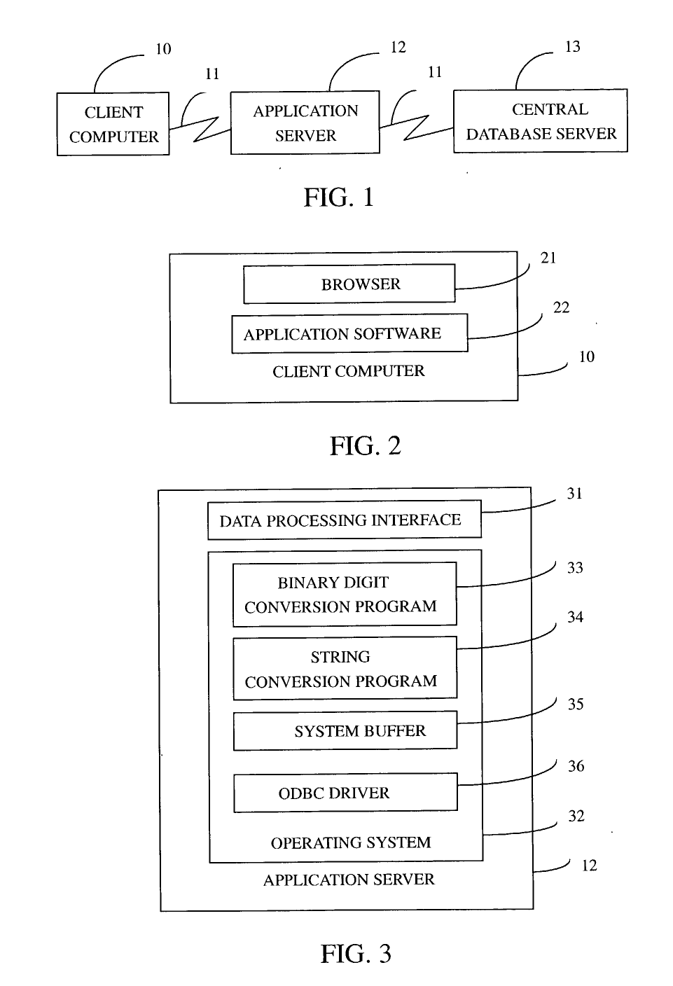

FIG. 2 is a structural diagram of the client computer 10 of FIG. 1. The client computer 10 connects with a network of an Internet Service Provider (ISP), an intranet or the Internet, and downloads patent data from national patent databases in multiple encodings via the Internet. The patent data is then transferred to the application server 12, and is processed therein. Finally, the patent data is stored in the central database server 13. The client computer 10 comprises a browser 21 and application software 22. The browser 21 can, for example, be Internet Explorer made by Microsoft. The browser 21 can invoke programs of an operating system of the client computer 10, to convert multiple encoded patent data downloaded from the Internet into Unicode strings. The application software 22 invokes the browser 21 to download patent data, transfer patent data, display patent data, display a catalog of patent data in the central database server 13, provide tools for analyzing patent data, and send requests to access patent data in the central database server 13.

In an alternative embodiment of the present invention, the client computer 10 comprises only application software, and does not comprise any browser. The application software can send requests of users in Javascript to a Hypertext Transfer Protocol (HTTP) network proxy. The proxy can send the requests over the Internet, and receive replies over the Internet. The application software can then download patent data directly in a remote patent data database. The application software can also invoke programs of an operating system of the client computer 10 to convert patent data downloaded from the Internet into Unicode strings.

FIG. 3 is a structural diagram of the application server 12 of FIG. 1. The application server 12 comprises a data processing interface 31 and an operating system 32. The operating system 32 comprises a binary digit conversion program 33, a string conversion program 34, a system buffer 35, and an Open Database Connectivity (ODBC) driver 36. Because Unicode is in the form of strings and all processes in the central database server 13 are in the form of binary digits, Unicode strings must be converted into binary digits before they are stored in the central database server 13. Conversely, binary digits must be converted into Unicode strings when they are displayed on the client computer 10. The application server 12 of the present invention provides the binary digit conversion program 33 and the string conversion program 34 to implement these conversions. The data processing interface 31 is for receiving data from the client computer 10 and the central database server 13. The data processing interface 31 can also receive a request for accessing of patent data in the central database server 13 from the client computer 10, create related Structured Query Language (SQL), and send the SQL to the central database server 13. In the process of interconversion between binary digits and Unicode strings, the data processing interface 31 invokes the binary digit conversion program 33 and the string conversion program 34. First, the data processing interface 31 invokes the binary digit conversion program 33 of the operating system 32 to convert Unicode strings received from the client computer 10 into binary digits. Language setting data of the operating system 32 is added in the head of the binary digits as a parameter, also in the form of binary digits. Then, the data processing interface 31 sends the binary digits to the system buffer 35 of the application server 12. Finally, the binary digits are sent to and stored in the central database server 13. The process of accessing patent data in the central database server 13 is essentially the opposite. When the application server 12 receives binary digits from the central database server 13, the data processing interface 31 invokes the string conversion program 34 to convert the binary digits into Unicode strings. The Unicode strings are then transferred to the client computer 10.

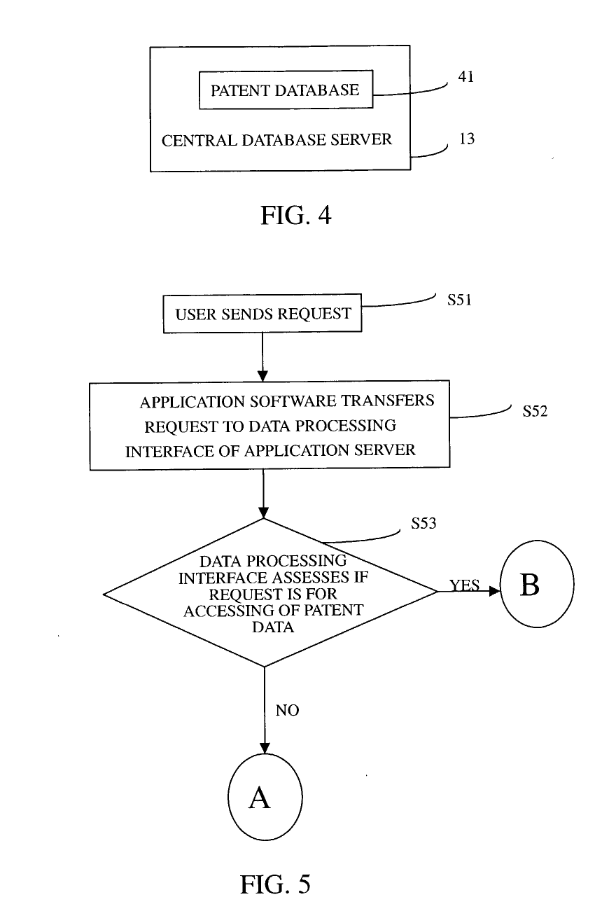

FIG. 4 is a structural diagram of the central database server 13 of FIG. 1. The central database server 13 comprises a patent database 41 that stores patent data in the form of binary digits. The central database server 13 implements SQL created by the application server 12, and searches for relevant patent data.

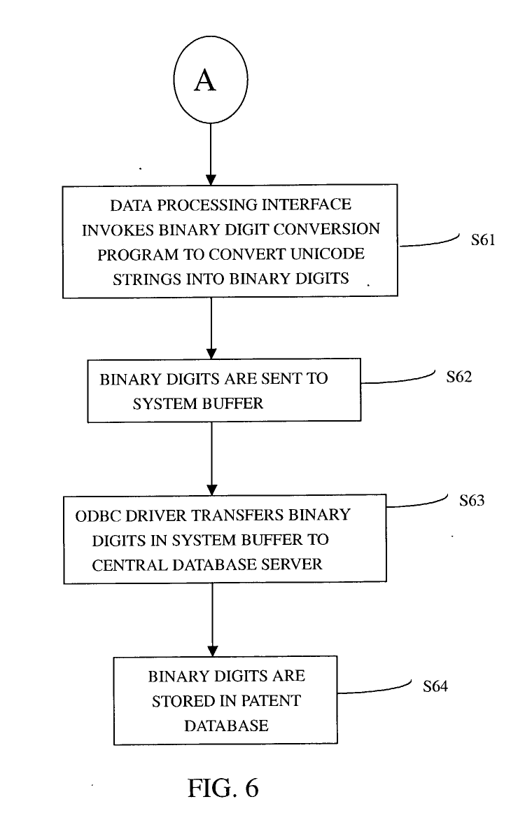

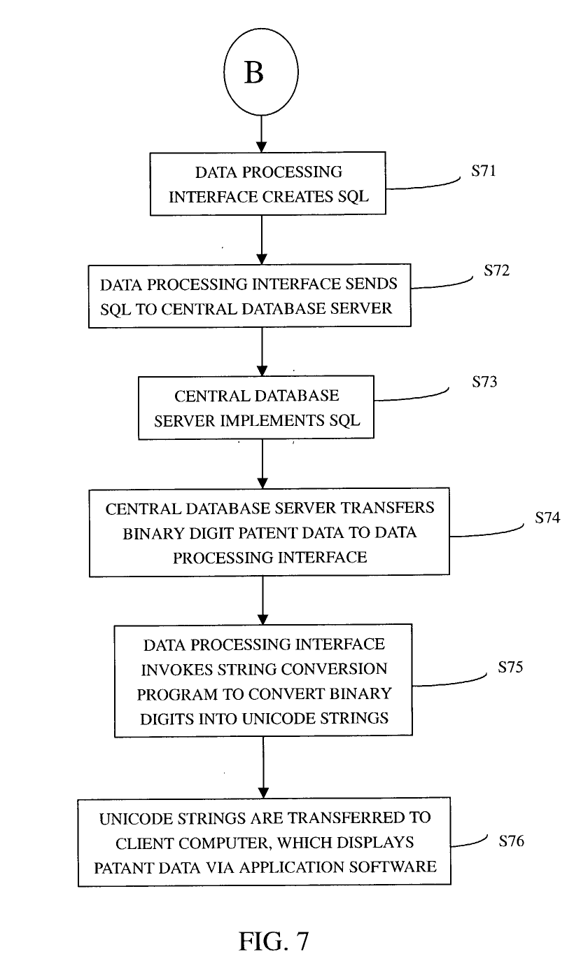

FIGS. 5, 6 and 7 are flowcharts of a method for displaying patent data in multiple encodings in accordance with a preferred embodiment of the present invention. In step S51, a user sends a request to the application software 22 of the client computer 10. The request can be either for storing of patent data in the patent database 41, or for accessing of patent data in the patent database 41. In step S52, the application software 22 transfers the request to the data processing interface 31 of the application server 12. In step S53, the data processing interface 31 assesses the request. If the request is not for accessing of patent data in the patent database 41, the procedure continues to step “A,” which is described in detail with reference to FIG. 6. As shown in FIG. 6, in step S61, the data processing interface 31 invokes the binary digit conversion program 33 of the operating system 32 to convert Unicode strings into binary digits. In step S62, the binary digits are sent to the system buffer 35. In step S63, the ODBC driver 36 transfers the binary digits in the system buffer 35 to the central database server 13. In step S64, the binary digits are stored in the patent database 41. If the request is for accessing of patent data in the patent database 41, the procedure instead continues to step “B,” which is described in detail with reference to FIG. 7. As shown in FIG. 7, in step S71, the data processing interface 31 creates SQL in accordance with the request. In step S72, the data processing interface 31 sends the SQL to the central database server 13. In step S73, the central database server 13 implements the SQL to search for relevant patent data in the patent database 41. In step S74, the central database server 13 transfers binary digit patent data found by the SQL and sent from the patent database 41 to the data processing interface 31. step S75, the data processing interface 31 invokes the string conversion program 34 to convert the binary digits into Unicode strings. In step S76, the Unicode strings are transferred to the client computer 10. The application software 22 of the client computer 10 displays the desired patent data on the client computer 10.

It is to be understood, however, that even though numerous characteristics and advantages of the present invention have been set forth in the foregoing description, together with details of the structure and performance of the invention, the disclosure is illustrative only, and changes may be made in detail, especially in matters of arrangement of parts and procedures within the principles of the invention to the full extent indicated by the broad general meaning of the terms in which the appended claims are expressed.

What is claimed is:

1. A system for displaying patent data in multiple encodings, the system comprising:
a client computer connected to the Internet; an application server; and
a database server, wherein:
the database server is used for storing patent data downloaded by the client computer;
the client computer is used for downloading patent data via the Internet and accessing patent data in the database server;
the client computer comprises application software for downloading patent data via the Internet, sending a request to access patent data in the database server, and displaying patent data in the form of Unicode strings on the client computer; and
the application server comprises a data processing interface for interconversion of binary digits and Unicode strings by invoking a binary digit conversion program and a string conversion program of the application server.

2. The system for displaying patent data in multiple encodings as claimed in claim 1, wherein the client computer, the application server and the database server are connected by an intranet.

3. The system for displaying patent data in multiple encodings as claimed in claim 1, wherein the client computer comprises a browser invoked by the application software to download patent data via the Internet.

4. A method for displaying patent data in multiple encodings, the method comprising the steps of:
(a) sending patent data required by a user to an application server in the form of binary digits;
(b) converting the binary digits into Unicode strings; and
(c) sending the patent data in the form of Unicode strings to a client computer for displaying the patent data to the user.

5. The method for displaying patent data in multiple encodings as claimed in claim 4, wherein the step of converting the binary digits into Unicode strings comprises the steps of:
(b1) receiving binary digit patent data from a database server;
(b2) invoking a string conversion program to convert the binary digits into Unicode strings; and
(b3) sending the Unicode strings to a system buffer of the application server.

6. The method for displaying patent data in multiple encodings as claimed in claim 4, wherein the step of converting the binary digits into Unicode strings comprises the step of:
sending the Unicode strings from the system buffer to application software of the client computer.

7. A method for displaying data in multiple encodings, the method comprising the steps of:
(a) sending data required by a user to an application server in the form of binary digits;
(b) converting the binary digits into Unicode strings; and
(c) sending the data in the form of Unicode strings from the application server to a client computer for displaying the data to the user.

8. The method for displaying data in multiple encodings as described in claim 7, wherein the step of converting the binary digits into Unicode strings comprises the steps of:
(b1) receiving binary digit data;
(b2) invoking a string conversion program to convert the binary digits into Unicode strings; and
(b3) sending the Unicode strings to a system buffer of the application server.

9. The method for displaying data in multiple encodings as described in claim 7, wherein the step of converting the binary digits into Unicode strings comprises the step of:
sending the Unicode strings from the system buffer to application software of the client computer.

10. A communication arrangement between a client computer and a plurality of databases of which at least one uses a system language different from that of said client computer, wherein via an application server, the client computer is linked to said databases for either downloading or uploading, said application server being equipped with a data processing interface for interconversion between binary digits and Unicode strings wherein data are stored in form of the binary digits in the databases while displayed in form of the Unicode strings in the computer.

11. The arrangement as claimed in claim 10, wherein said databases are derived from different languages used by different nations.
